(19) United States
(12) Patent Application Publication
(10) Pub. No.: US 2025/0174500 A1
(43) Pub. Date: May 29, 2025

(54) SEMICONDUCTOR PACKAGE WITH SYSTEM TEST RING

(71) Applicant: MEDIATEK INC., Hsinchu City (TW)

(72) Inventors: Cing-Yao Jhan, Hsinchu City (TW); Chien-Kai Huang, Hsinchu City (TW); Ting-Chen Shih, Hsinchu City (TW); Chu-Wei Hu, Hsinchu City (TW)

(73) Assignee: MEDIATEK INC., Hsinchu City (TW)

(21) Appl. No.: 18/929,634

(22) Filed: Oct. 29, 2024

Related U.S. Application Data
(60) Provisional application No. 63/603,693, filed on Nov. 29, 2023.

(51) Int. Cl. H01L 21/66; H01L 23/538; H01L 25/065

(52) U.S. Cl. CPC H01L 22/32; H01L 23/538; H01L 25/0652; H01L 25/0655; H01L 25/0657; H01L 2225/06527; H01L 2225/06596

(57) ABSTRACT

The present disclosure provides a semiconductor package including a first integrated circuit die having a first on-die test ring thereon; a second integrated circuit die having a second on-die test ring thereon; and a system test ring constructed by connecting the first on-die test ring and the second on-die test ring. The system test ring allows for detection of damage to the individual integrated circuit die assembled in one package on a system level.

### CROSS REFERENCE TO RELATED APPLICATIONS

This application claims the benefit of U.S. Provisional Application No. 63/603,693, filed on Nov. 29, 2023. The content of the application is incorporated herein by reference.

### BACKGROUND

The present disclosure relates to the field of semiconductor technology. More specifically, the present disclosure relates to a device for detection of damages in semiconductor die package on system level.

As known in the art, semiconductor die edge is susceptible to manufacturing defects such as die chipping or cracking. The die chipping or cracking at die edges may be caused by, for example, wafer sawing, die handling or test. To detect failures or defects including those caused by cracks near the die edges, an edge die monitor (EDM) or defect detection structure is typically provided around a periphery of the die.

There is a need in this industry to provide an improved device for detection of damages in semiconductor die package on system level.

### SUMMARY

It is one object of the present disclosure to provide an improved semiconductor package with system test ring in order to solve the prior art deficiencies or shortcomings.

One aspect of the present disclosure provides a semiconductor package including a first integrated circuit die having a first on-die test ring thereon; a second integrated circuit die having a second on-die test ring thereon; and a system test ring constructed by connecting the first on-die test ring and the second on-die test ring.

According to some embodiments, the first on-die test ring is connected to the second on-die test ring through a substrate.

According to some embodiments, the substrate comprises an interposer, a packaging substrate, or a printed circuit board.

According to some embodiments, the first integrated circuit die is stacked directly on the second integrated circuit die.

According to some embodiments, connection between the first on-die test ring and the second on-die test ring comprises copper-to-copper direct bonding, through silicon vias, through mold vias, through substrate vias, solder balls, micro-bumps, re-distribution layers, or any combinations thereof.

According to some embodiments, the first integrated circuit die and the second integrated circuit die are mounted on the substrate in a side-by-side manner.

According to some embodiments, the first on-die test ring comprises a first terminal coupled to a first bridge structure of the substrate and a second terminal coupled to a second bridge structure of the substrate.

According to some embodiments, the second on-die test ring comprises a third terminal coupled to the first bridge structure of the substrate and a fourth terminal coupled to the second bridge structure of the substrate.

According to some embodiments, connection between the first on-die test ring, the second on-die test ring, and the substrate comprises through silicon vias, through substrate vias, solder balls, micro-bumps, or any combinations thereof.

According to some embodiments, the first integrated circuit die comprises a system-on-chip die, a central processing unit die, a graphic processing unit die, an RF die, an application processor die, or a memory die.

According to some embodiments, the second integrated circuit die comprises a system-on-chip die, a central processing unit die, a graphic processing unit die, an RF die, an application processor die, or a memory die.

According to some embodiments, each of the first on-die test ring and the second on-die test ring has a rectangular shape and four edges.

According to some embodiments, each of the first on-die test ring and the second on-die test ring comprises a first terminal, a second terminal, an electro-static discharge (ESD) units disposed near the first terminal, and a plurality of damage detection elements.

According to some embodiments, the first terminal is an input port that is used to provide a test signal, and wherein the second terminal is an output port that is coupled to ground.

According to some embodiments, the plurality of damage detection elements comprises diodes, resistors, capacitors, invertors, or flip-flops.

These and other objectives of the present invention will no doubt become obvious to those of ordinary skill in the art after reading the following detailed description of the preferred embodiment that is illustrated in the various figures and drawings.

### BRIEF DESCRIPTION OF THE DRAWINGS

The accompanying drawings are included to provide a further understanding of the invention, and are incorporated in and constitute a part of this specification. The drawings illustrate embodiments of the invention and, together with the description, serve to explain the principles of the invention. In the drawings:

FIG. 1 is a perspective, schematic diagram showing an exemplary semiconductor package in accordance with one embodiment of the invention;

FIG. 2 illustrates an exemplary semiconductor die having an on-die test ring;

FIG. 3 is a schematic diagram showing an exemplary semiconductor package in accordance with another embodiment of the invention; and

FIG. 4 is a perspective, schematic diagram showing an exemplary semiconductor package in accordance with still another embodiment of the invention.

### DETAILED DESCRIPTION

In the following detailed description of embodiments of the invention, reference is made to the accompanying drawings, which form a part hereof, and in which is shown by way of illustration specific preferred embodiments in which the disclosure may be practiced.

These embodiments are described in sufficient detail to enable those skilled in the art to practice them, and it is to be understood that other embodiments may be utilized and that mechanical, chemical, electrical, and procedural changes may be made without departing from the spirit and scope of the present disclosure. The following detailed description is, therefore, not to be taken in a limiting sense, and the scope of embodiments of the present invention is defined only by the appended claims.

It will be understood that when an element or layer is referred to as being “on”, “connected to” or “coupled to” another element or layer, it can be directly on, connected or coupled to the other element or layer or intervening elements or layers may be present. In contrast, when an element is referred to as being “directly on,” “directly connected to” or “directly coupled to” another element or layer, there are no intervening elements or layers present. Like numbers refer to like elements throughout. As used herein, the term “and/or” includes any and all combinations of one or more of the associated listed items. The term “dummy die”, which is a non-function die, is referred to as a semiconductor die or chip that does not have any electrical function.

The present disclosure pertains to a multi-die package device, such as 2.5D or 3D IC packages, including a system test ring constructed by connecting on-die test rings. Each of the on-die test rings may be located in a seal ring disposed around a periphery of an integrated circuit (IC) die of the multi-die package device. The system test ring may be used to detect damage to the IC die or defects in the multi-die package device caused during assembly on a system level. The present invention is suited for applications including, but not limited to, System-on-Integrated-Chip (SoIC) package-on-package (PoP), or Chip-on-Wafer-on-Substrate (CoWoS) packages.

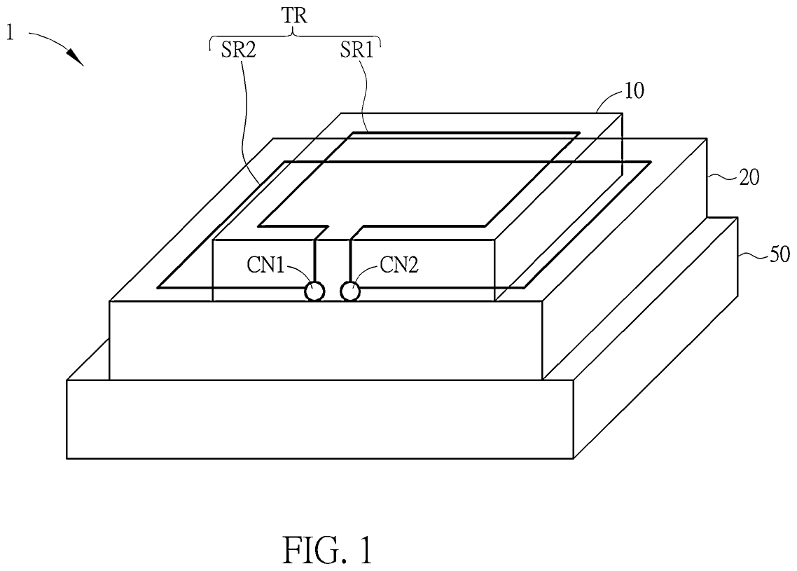

FIG. 1 is a perspective, schematic diagram showing an exemplary semiconductor package in accordance with one embodiment of the invention. As shown in FIG. 1, the semiconductor package 1 may comprise a first integrated circuit (IC) die 10 having a first on-die test ring SR1 fabricated thereon, a second IC die 20 having a second on-die test ring SR2 fabricated thereon, and a substrate 50. According to an embodiment of the invention, the first IC die 10 is stacked on the second IC die 20. According to an embodiment of the invention, the second IC die 2 may be stacked on the substrate 50. For example, the substrate 50 may comprise an interposer, a packaging substrate, or a printed circuit board.

According to an embodiment of the invention, for example, the first IC die 10 may be a system-on-chip (SoC) die, a central processing unit (CPU) die, a graphic processing unit (GPU) die, an RF die, an application processor (AP) die, or a memory die. According to an embodiment of the invention, for example, the second IC die 20 may be a SoC die, a CPU die, a GPU die, an RF die, an AP die, or a memory die. The memory die may be a high-bandwidth memory (HBM) die comprised of a stack of DRAM dies, but not limited thereto. According to an embodiment, for example, the HBM die may be HBM2 or HBM3, but not limited thereto. HBM is a memory chip with low power consumption and ultra-wide communication lanes.

According to an embodiment of the invention, the semiconductor package 1 may further comprise a system test ring TR constructed by connecting the first on-die test ring SR1 and the second on-die test ring SR2. According to an embodiment of the invention, the first on-die test ring SR1 may be located in a seal ring disposed around a periphery of the first IC die 10. According to an embodiment of the invention, the second on-die test ring SR2 may be located in a seal ring disposed around a periphery of the second IC die 20. The connection points CN1 and CN2 between the first on-die test ring SR1 and the second on-die test ring SR2 may include, but not limited to, copper-to-copper direct bonding, through silicon vias, through mold vias, through substrate vias, solder balls, micro-bumps, re-distribution layers, or any combinations thereof.

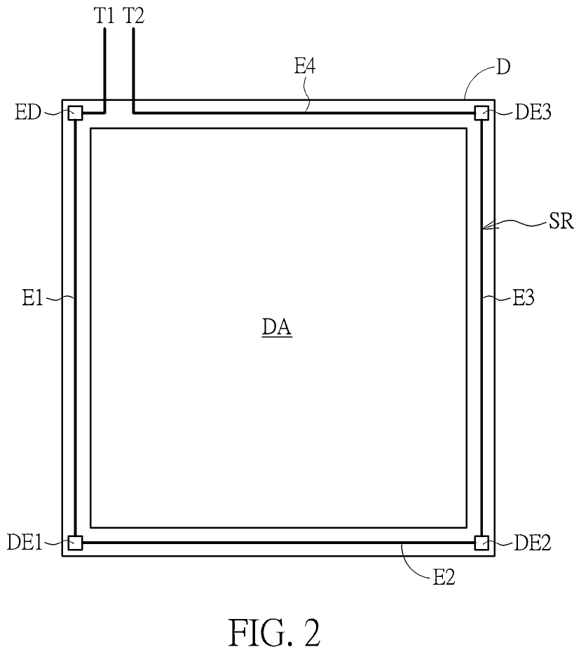

FIG. 2 illustrates an exemplary semiconductor die having an on-die test ring. As shown in FIG. 2, the semiconductor die D comprises an integrated circuit region DA and an on-die test ring SR extending along a perimeter of the integrated circuit region DA. The on-die test ring SR may have a rectangular shape and may have four edges: E1-E4. The on-die test ring SR may comprise a first terminal T1, a second terminal T2, an optional electro-static discharge (ESD) units ED disposed near the first terminal T1, and multiple damage detection elements DE1-DE3. According to an embodiment of the invention, the damage detection elements DE1-DE3 may comprise diodes, resistors, capacitors, invertors, or flip-flops, but not limited thereto. It is understood that the number and arrangement of the multiple damage detection elements in FIG. 2 are for illustration purposes only.

According to an embodiment of the invention, the first terminal T1 may be an input port that may be used to provide a test signal to the on-die test ring SR. According to an embodiment of the invention, the second terminal T2 may be an output port that may be coupled to ground. The test results may be obtained at the second terminal T2. The ESD units ED provides protection to the multiple damage detection elements DE1-DE3. According to an embodiment of the invention, the first terminal T1 and/or the second terminal T2 may be used as a connection point/pad to an on-die test ring of another integrated circuit die. In some embodiments, additional connection pads may be formed on the on-die test ring SR for connection with an on-die test ring of another integrated circuit die.

It is understood that the system test ring TR in FIG. 1 may be connected to an input port for providing a test signal and an output port connected to ground, which are not shown for the sake of simplicity. The input port and the output port may be disposed at suitable positions system test ring TR depending upon design requirements.

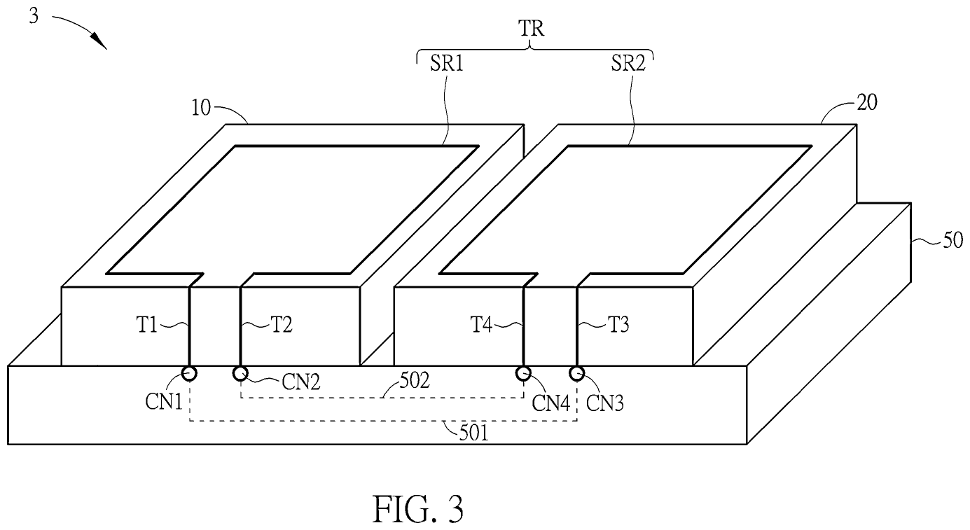

FIG. 3 is a schematic diagram showing an exemplary semiconductor package in accordance with another embodiment of the invention, wherein like numeral numbers designate like regions, layers or elements. As shown in FIG. 3, the semiconductor package 3 may comprise a first IC die 10 having a first on-die test ring SR1 fabricated thereon, a second IC die 20 having a second on-die test ring SR2 fabricated thereon, and a substrate 50. According to an embodiment of the invention, the first IC die 10 and the second IC die 20 are mounted on the substrate 50 in a side-by-side manner. According to an embodiment of the invention, for example, the first IC die 10 and the second IC die 20 may be flip chips and may be mounted on the substrate 50 in a flip-chip fashion. For example, the substrate 50 may comprise an interposer, a packaging substrate, or a printed circuit board.

According to an embodiment of the invention, for example, the first IC die 10 may be a SoC die, a CPU die, a GPU die, an RF die, an AP die, or a memory die. According to an embodiment of the invention, for example, the second IC die 20 may be a SoC die, a CPU die, a GPU die, an RF die, an AP die, or a memory die. The memory die may be a high-bandwidth memory (HBM) die comprised of a stack of DRAM dies, but not limited thereto. According to an embodiment, for example, the HBM die may be HBM2 or HBM3, but not limited thereto. According to an embodiment of the invention, the first IC die 10 and the second IC die 20 may be different function dies.

According to an embodiment of the invention, likewise, the semiconductor package 3 may further comprise a system test ring TR constructed by connecting the first on-die test ring SR1 and the second on-die test ring SR2 together into a ring circuit. According to an embodiment of the invention, the first on-die test ring SR1 may be located in a seal ring disposed around a periphery of the first IC die 10. According to an embodiment of the invention, the second on-die test ring SR2 may be located in a seal ring disposed around a periphery of the second IC die 20. The structure of the first on-die test ring SR1 and the second on-die test ring SR2 is shown in FIG. 2.

According to an embodiment of the invention, the first on-die test ring SR1 comprises a first terminal T1 coupled to a first bridge structure 501 of the substrate 50 and a second terminal T2 coupled to a second bridge structure 502 of the substrate 50. According to an embodiment of the invention, the second on-die test ring SR2 comprises a third terminal T3 coupled to the first bridge structure 501 of the substrate 50 and a fourth terminal T4 coupled to the second bridge structure 502 of the substrate 50. According to an embodiment of the invention, for example, the substrate 50 may be a silicon interposer, and the first bridge structure 501 and the second bridge structure 502 may be metal interconnect structure formed in the substrate 50. The connection points CN1-CN4 between the first on-die test ring SR1, the second on-die test ring SR2, and the substrate 50 may include, but not limited to, through silicon vias, through substrate vias, solder balls, micro-bumps, or any combinations thereof.

The system test ring TR allows for detection of damage to the individual integrated circuit die assembled in one package on a system level. In some embodiments, there may be more than two IC dies on the substrate 50. For example, in some embodiments, four IC dies may be mounted on the substrate 50 so as to form an integrated chiplet structure.

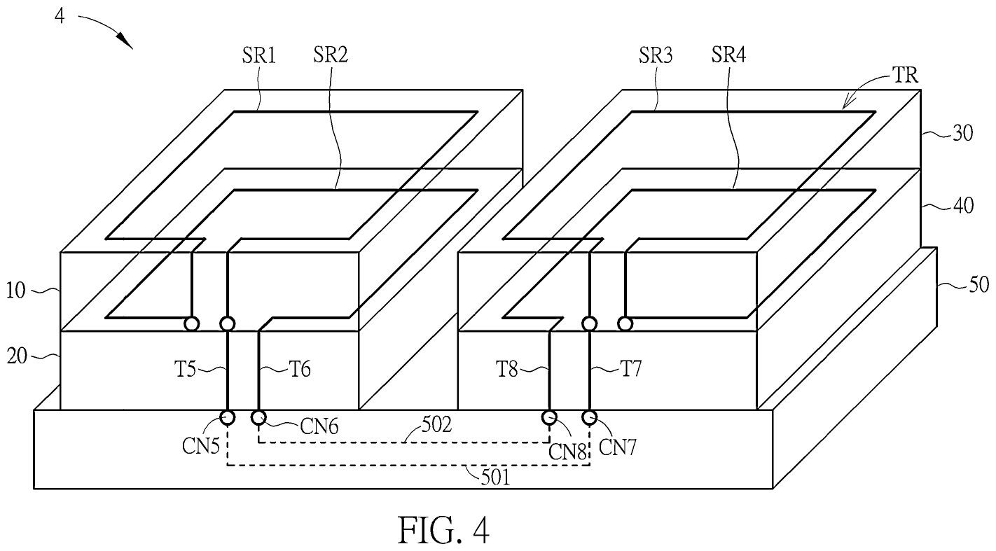

FIG. 4 is a perspective, schematic diagram showing an exemplary semiconductor package in accordance with still another embodiment of the invention, wherein like numeral numbers designate like regions, layers or elements. As shown in FIG. 4, the semiconductor package 4 may comprise a first IC die 10 having a first on-die test ring SR1 fabricated thereon, a second IC die 20 having a second on-die test ring SR2 fabricated thereon, a third IC die 30 having a third on-die test ring SR3 fabricated thereon, a fourth IC die 40 having a fourth on-die test ring SR4 fabricated thereon, and a substrate 50.

According to an embodiment of the invention, the first IC die 10 is stacked on the second IC die 20. According to an embodiment of the invention, the third IC die 30 is stacked on the fourth IC die 40. The second IC die 20 is directly mounted on the substrate 50. The fourth IC die 40 is directly mounted on the substrate 50. According to an embodiment of the invention, for example, the first IC die 10 and the third IC die 30 may be flip chips, but not limited thereto. For example, the substrate 50 may comprise an interposer, a packaging substrate, or a printed circuit board.

According to an embodiment of the invention, for example, the first IC die 10 may be a SoC die, a CPU die, a GPU die, an RF die, an AP die, or a memory die. According to an embodiment of the invention, for example, the second IC die 20 may be a SoC die, a CPU die, a GPU die, an RF die, an AP die, or a memory die. According to an embodiment of the invention, for example, the third IC die 30 may be a SoC die, a CPU die, a GPU die, an RF die, an AP die, or a memory die. According to an embodiment of the invention, for example, the fourth IC die 40 may be a SoC die, a CPU die, a GPU die, an RF die, an AP die, or a memory die. The memory die may be a high-bandwidth memory (HBM) die comprised of a stack of DRAM dies, but not limited thereto. According to an embodiment, for example, the HBM die may be HBM2 or HBM3, but not limited thereto. According to an embodiment of the invention, the first IC die 10, the second IC die 20, the third IC die 30, and the fourth IC die 40 may be mutually different function dies.

According to an embodiment of the invention, likewise, the semiconductor package 4 may further comprise a system test ring TR constructed by connecting the first on-die test ring SR1, the second on-die test ring SR2, the third on-die test ring SR3, and the fourth on-die test ring SR4 together into a ring circuit. According to an embodiment of the invention, the first on-die test ring SR1 may be located in a seal ring disposed around a periphery of the first IC die 10. According to an embodiment of the invention, the second on-die test ring SR2 may be located in a seal ring disposed around a periphery of the second IC die 20. According to an embodiment of the invention, the third on-die test ring SR3 may be located in a seal ring disposed around a periphery of the third IC die 30. According to an embodiment of the invention, the fourth on-die test ring SR4 may be located in a seal ring disposed around a periphery of the fourth IC die 40.

According to an embodiment of the invention, the connection between the first on-die test ring SR1 and the second on-die test ring SR2 may include, but not limited to, copper-to-copper direct bonding, through silicon vias, through mold vias, through substrate vias, solder balls, micro-bumps, re-distribution layers, or any combinations thereof. According to an embodiment of the invention, the connection between the third on-die test ring SR3 and the fourth on-die test ring SR4 may include, but not limited to, copper-to-copper direct bonding, through silicon vias, through mold vias, through substrate vias, solder balls, micro-bumps, re-distribution layers, or any combinations thereof.

According to an embodiment of the invention, the second on-die test ring SR2 comprises a fifth terminal T5 coupled to a first bridge structure 501 of the substrate 50 and a sixth terminal T6 coupled to a second bridge structure 502 of the substrate 50. According to an embodiment of the invention, the fourth on-die test ring SR4 comprises a seventh terminal T7 coupled to the first bridge structure 501 of the substrate 50 and a eighth terminal T8 coupled to the second bridge structure 502 of the substrate 50. According to an embodiment of the invention, for example, the substrate 50 may be a silicon interposer, and the first bridge structure 501 and the second bridge structure 502 may be metal interconnect structure formed in the substrate 50. The connection points CN5-CN8 between the second on-die test ring SR1, the fourth on-die test ring SR2, and the substrate 50 may include, but not limited to, through silicon vias, through substrate vias, solder balls, micro-bumps, or any combinations thereof.

Those skilled in the art will readily observe that numerous modifications and alterations of the device and method may be made while retaining the teachings of the invention. Accordingly, the above disclosure should be construed as limited only by the metes and bounds of the appended claims.

What is claimed is:

1. A semiconductor package, comprising:
a first integrated circuit die having a first on-die test ring thereon;
a second integrated circuit die having a second on-die test ring thereon; and
a system test ring constructed by connecting the first on-die test ring and the second on-die test ring.

2. The semiconductor package according to claim 1, wherein the first on-die test ring is connected to the second on-die test ring through a substrate.

3. The semiconductor package according to claim 2, wherein the substrate comprises an interposer, a packaging substrate, or a printed circuit board.

4. The semiconductor package according to claim 1, wherein the first integrated circuit die is stacked directly on the second integrated circuit die.

5. The semiconductor package according to claim 4, wherein connection between the first on-die test ring and the second on-die test ring comprises copper-to-copper direct bonding, through silicon vias, through mold vias, through substrate vias, solder balls, micro-bumps, re-distribution layers, or any combinations thereof.

6. The semiconductor package according to claim 2, wherein the first integrated circuit die and the second integrated circuit die are mounted on the substrate in a side-by-side manner.

7. The semiconductor package according to claim 6, wherein the first on-die test ring comprises a first terminal coupled to a first bridge structure of the substrate and a second terminal coupled to a second bridge structure of the substrate.

8. The semiconductor package according to claim 7, wherein the second on-die test ring comprises a third terminal coupled to the first bridge structure of the substrate and a fourth terminal coupled to the second bridge structure of the substrate.

9. The semiconductor package according to claim 8, wherein connection between the first on-die test ring, the second on-die test ring, and the substrate comprises through silicon vias, through substrate vias, solder balls, micro-bumps, or any combinations thereof.

10. The semiconductor package according to claim 1, wherein the first integrated circuit die comprises a system-on-chip die, a central processing unit die, a graphic processing unit die, an RF die, an application processor die, or a memory die.

11. The semiconductor package according to claim 1, wherein the second integrated circuit die comprises a system-on-chip die, a central processing unit die, a graphic processing unit die, an RF die, an application processor die, or a memory die.

12. The semiconductor package according to claim 1, wherein each of the first on-die test ring and the second on-die test ring has a rectangular shape and four edges.

13. The semiconductor package according to claim 1, wherein each of the first on-die test ring and the second on-die test ring comprises a first terminal, a second terminal, an electro-static discharge (ESD) units disposed near the first terminal, and a plurality of damage detection elements.

14. The semiconductor package according to claim 13, wherein the first terminal is an input port that is used to provide a test signal, and wherein the second terminal is an output port that is coupled to ground.

15. The semiconductor package according to claim 13, wherein the plurality of damage detection elements comprises diodes, resistors, capacitors, invertors, or flip-flops.
